(19) United States
(12) Patent Application Publication
(10) Pub. No.: US 2006/0152913 A1
(43) Pub. Date: Jul. 13, 2006

(54) Method and apparatus for reducing electromagnetic emissions from electronic circuits

(76) Inventors: Manuel Richey, Paola, KS (US); Kenneth Terry Reim, Spring Hill, KS (US)

Correspondence Address: Deborah Chess;Honeywell International Inc, 101 Columbia Road, Morristown, NJ, 07962, US

(21) Appl. No.: 10/524,667

(22) PCT Filed: Aug. 14, 2003
(86) PCT No.: PCT/US03/25461

§ 371 Date: Feb. 11, 2005

(30) Foreign Application Priority Data
Aug. 14, 2002 (US) 60403302

(51) Int. Cl. H05K 9/00

(52) U.S. Cl. 361/818; 174/260

(57) ABSTRACT

An electronic circuit (10) comprising at least one electrical component (12) and at least one grounding point (16) is provided that includes a first layer of non-conductive coating (18) and a second layer of conductive coating (20). The non-conductive coating (18) is applied over the electrical component (12) in such a manner that the grounding point (16) remains uncoated. The conductive coating (20) is applied over the non-conductive coating (18) and the grounding point (16) so as to ground the conductive coating (20). The conductive coating (20) thus shields the electrical component (12) to thereby reduce electromagnetic emissions from the electronic circuit (10). Various exemplary embodiments of the coated electronic circuit and associated method are provided.

### FIELD OF THE INVENTION

The present invention relates generally to electronic circuits, and more particularly to shielding electromagnetic emissions generated by electronic circuits.

### DESCRIPTION OF RELATED ART

Electronic circuits often generate electromagnetic fields that can interfere with the operation of other electronic circuits. In particular, high-speed electronic circuits (such as microprocessors or digital signal processors) tend to generate high levels of electromagnetic emissions. Sensitive electronic circuits located in close proximity to the high-speed electronic circuits can detect the electromagnetic emissions generated thereby. The result is electromagnetic interference (EMI) that can interfere with the operation of the proximate electronic circuits, or even cause the proximate electronic circuits to malfunction. Radio receivers, which are intentionally designed to be sensitive to electromagnetic signals, are especially susceptible to EMI.

In an effort to reduce or eliminate the effect of EMI, it is known to employ shielding around the electronic circuits that generate electromagnetic emissions. It is also known to employ various types of Faraday shields around the electronic circuits that are sensitive to EMI in order to reduce or eliminate the level of electromagnetic emissions reaching the sensitive circuits. There are a number of disadvantages, however, to these known types of shields. Because the shields are typically formed as metal cages or wire mesh that form a box around the electronic circuits, they are difficult to manufacture and relatively expensive to install over the electronic circuits. In addition, the box form of the shields does not conform to the profile of the electronic circuits and, thus, the shields are bulky and space inefficient. Other disadvantages should be apparent to those skilled in the art.

### BRIEF SUMMARY OF THE INVENTION

The present invention is directed to an electronic circuit that includes at least one electrical component and at least one grounding point, as well as a first layer of non-conductive coating and a second layer of conductive coating. The non-conductive coating is applied over the electrical component in such a manner that the non-conductive coating does not coat the grounding point. Preferably, the non-conductive coating conforms to the underlying electrical component so as to protect the electrical component from environmental conditions, such as exposure to water or humidity. The conductive coating is then applied over the non-conductive coating (and the underlying electrical component) and the grounding point so as to ground the conductive coating. The conductive coating thus acts as a shield for the electrical component to thereby reduce electromagnetic emissions from the electronic circuit. Preferably, the conductive coating conforms to the non-conductive coating (and the underlying electrical component) and the grounding point so as to minimize the space required for the electromagnetic emissions shield.

In a first exemplary embodiment, the coated electronic circuit includes a plurality of electrical components and a plurality of ground pads located proximate the edges of the electronic circuit. A non-conductive conformal coating is applied over all of the electrical components in such a manner that the edges and ground pads remain uncoated. A conductive conformal coating is then applied over the non-conductive coating and the edges and ground pads so as to ground the conductive conformal coating. The conductive conformal coating thus shields the electrical components to thereby reduce electromagnetic emissions from the electronic circuit.

In a second exemplary embodiment, the coated electronic circuit includes a single electrical component and a single ground pad. A non-conductive conformal coating is applied over the electrical component and the ground pad, wherein a hole is formed in the non-conductive coating above the ground pad such that at least a portion of the ground pad remains uncoated. A conductive conformal coating is then applied over the non-conductive coating such that the conductive conformal coating contacts the ground pad through the hole in the non-conductive conformal coating so as to ground the conductive conformal coating. The conductive conformal coating thus shields the electrical component to thereby reduce electromagnetic emissions from the electronic circuit.

### BRIEF DESCRIPTION OF THE DRAWINGS

FIG. 1 is a perspective view of an uncoated electronic circuit having a plurality of electrical components and a plurality of grounding points.

FIG. 2 is a side sectional view taken along line 2-2 of the electronic circuit of FIG. 1, wherein the electronic circuit further includes a first layer of non-conductive coating and a second layer of conductive coating in accordance with a first exemplary embodiment of the present invention.

FIG. 3 is a perspective view of the electronic circuit of FIG. 1, wherein the electronic circuit further includes a first layer of non-conductive coating and a second layer of conductive coating in accordance with a second exemplary embodiment of the present invention.

FIG. 4 is a side sectional view taken along line 3-3 of the electronic circuit of FIG. 3.

### DETAILED DESCRIPTION OF THE INVENTION

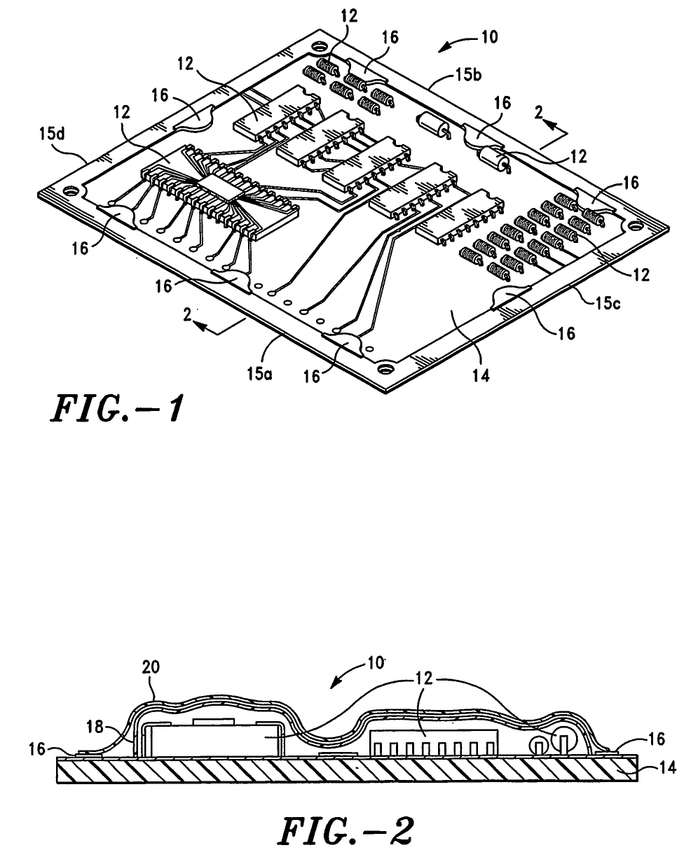

A typical electronic circuit is depicted in FIG. 1, and coated electronic circuits in accordance with exemplary embodiments of the present invention are depicted in FIGS. 2-4. While the invention will be described in detail hereinbelow with reference to these exemplary embodiments, it should be understood that the invention is not limited to the specific configurations of the electronic circuits shown in these embodiments. Rather, one skilled in the art will appreciate that a wide variety of configurations of electronic circuits may be implemented in accordance with the present invention.

Referring to FIG.1, a typical electronic circuit 10 is shown that includes a plurality of individual electrical components or circuits 12 mounted on a printed circuit board 14. It should be understood that the invention is not limited to any particular number or types of electrical components. Rather, the invention may be applied to any electronic circuit in which it is desired to reduce or eliminate electromagnetic emissions generated by one or more electrical components.

Electronic circuit 10 also includes a plurality of grounding points or ground pads 16 disposed around the perimeter of printed circuit board 14. In the illustrated embodiment, three ground pads are located proximate a first edge 15a of electronic circuit 10, three ground pads are located proximate a second edge 15b of electronic circuit 10, one ground pad is located proximate a third edge 15c of electronic circuit 10, and one ground pad is located proximate a fourth edge 15d of electronic circuit 10. Each of ground pads 16 is tied to the ground of electronic circuit 10 so as to provide a plurality of ground references for electronic circuit 10. It should be understood that the thickness of ground pads 16 has been exaggerated for purposes of illustration, and that most ground pads will typically have the same thickness as the traces on printed circuit board 14 such that they do not project substantially above the plane of printed circuit board 14.

Turning now to FIG. 2, electronic circuit 10 is shown with a first layer of non-conductive coating 18 and a second layer of conductive coating 20 in accordance with a first exemplary embodiment of the present invention. In this embodiment, non-conductive coating 18 is applied over all of electrical components 12 in such a manner that non-conductive coating 18 coats all of electronic circuit 10 except edges 15a-15d. As such, all of ground pads 16 remain uncoated. Masking or release may also be used to prevent non-conductive coating 18 from adhering to ground pads 16. Preferably, non-conductive coating 18 conforms to the profile of electrical components 12 so as to protect electrical components 12 from environmental conditions, such as exposure to water or humidity. Non-conductive coating 18 may comprise any type of non-conductive conformal coating material that is known in the art, such as insulating tape, rubber, silicone, room-temperature vulcanizing (RTV) silicone rubber, plastic, insulating varnish, or any other non-conductive coating material.

Conductive coating 20 is applied over non-conductive coating 18 (and thus over underlying electrical components 12) and grounds pads 16 in such a manner that conductive coating 20 coats substantially all of electronic circuit 10. As such, conductive coating 20 contacts each of ground pads 16 to thereby ground conductive coating 20. Conductive coating 20 thus acts as a shield for electrical components 12 to thereby reduce or eliminate electromagnetic emissions from electronic circuit 10. Preferably, conductive coating 20 conforms to non-conductive coating 18 (and thus the profile of underlying electrical components 12) and grounds pads 16 so as to minimize the space required for the electromagnetic emissions shield. Conductive coating 20 may comprise any type of conductive conformal coating material that is known in the art, such as conductive tape, conductive paint, and conductive silver paint.

In the illustrated embodiment, conductive coating 20 is applied so as to contact each of ground pads 16 located around the perimeter of printed circuit board 14. It should be understood, however, that conductive coating 20 need only contact a portion of a single ground pad in order to provide grounding to electronic circuit 10. Thus, conductive coating 20 may be applied so as to contact less than all of ground pads 16, such as a single ground pad or only a portion of a single ground pad. Similarly, non-conductive coating 18 may be applied so as to coat one or more of ground pads 16, provided that at least a portion of a single ground pad remains uncoated for contact with conductive coating 20. Thus, it should be understood that the application of non-conductive coating 18 and conductive coating 20 may vary in accordance with the present invention.

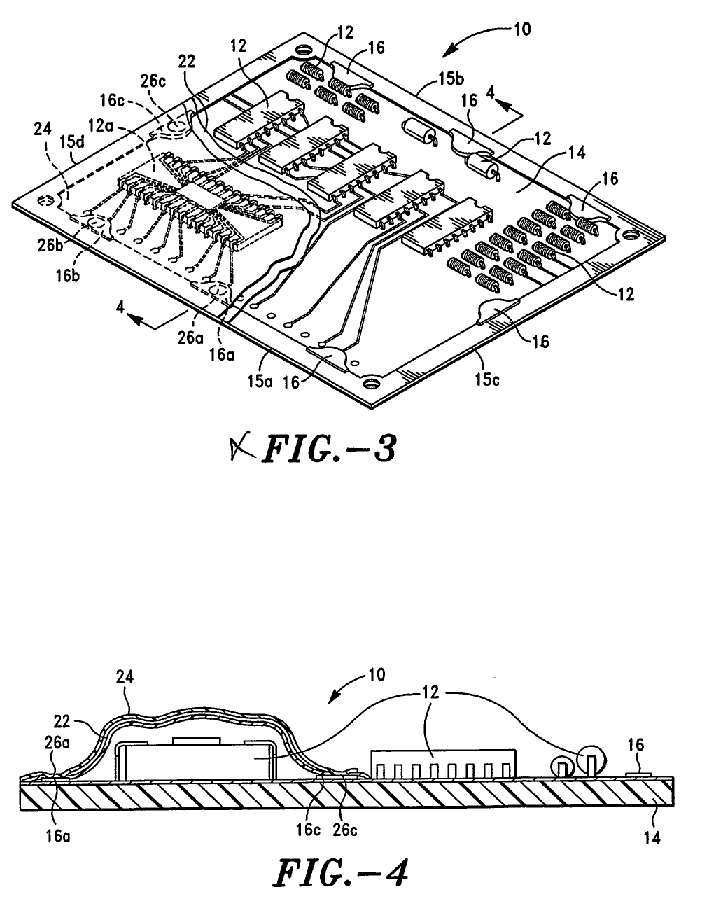

Turning now to FIGS. 3 and 4, electronic circuit 10 is shown with a first layer of non-conductive coating 22 and a second layer of conductive coating 24 in accordance with a second exemplary embodiment of the present invention. In this embodiment, non-conductive coating 22 is applied over a single electrical component, which has been labeled as reference numeral 12a in FIGS. 3 and 4 for ease of reference. As can be seen, non-conductive coating 22 coats electrical component 12a and extends over a portion of edges 15a and 15d (and thus over three ground pads that have been labeled as reference numerals 16a, 16b and 16c in FIGS. 3 and 4 for ease of reference). However, the remaining portion of electronic circuit 10 remains uncoated. Preferably, non-conductive coating 22 conforms to the profile of electrical component 12a for environmental protection. Non-conductive coating 22 may comprise any type of non-conductive conformal coating material that is known in the art, such as insulating tape, rubber, silicone, room-temperature vulcanizing (RTV) silicone rubber, plastic, insulating varnish, or any other non-conductive coating material.

As best seen in FIG. 4, holes 26a, 26b and 26c are formed in non-conductive coating 22 directly above ground pads 16a, 16b and 16c, respectively. As such, ground pads 16a, 16b and 16c remain uncoated. Holes 26a, 26b and 26c may be formed by masking ground pads 16a, 16b and 16c prior to applying non-conductive coating 22 such that non-conductive coating 22 does not adhere to the masked areas. Alternatively, holes 26a, 26b and 26c may be formed after the application of non-conductive coating 22 by cutting or removing the portions of non-conductive coating 22 directly above ground pads 16a, 16b and 16c. Of course, it should be understood that other methods may also be used to form holes 26a, 26b and 26c in non-conductive coating 22.

Conductive coating 24 is applied over substantially all of non-conductive coating 22 (and thus over underlying electrical component 12a and grounds pads 16a, 16b and 16c). As best seen in FIG. 4, conductive coating 24 extends into holes 26a, 26b and 26c formed in non-conductive coating 22 so as to contact ground pads 16a, 16b and 16c and thereby ground conductive coating 24. Conductive coating 24 thus acts as a shield for electrical component 12a to thereby reduce or eliminate electromagnetic emissions therefrom. Preferably, conductive coating 24 conforms to non-conductive coating 22 (and thus the profile of underlying electrical component 12a) and grounds pads 16a, 16b and 16c so as to minimize the space required for the electromagnetic emissions shield. Conductive coating 24 may comprise any type of conductive conformal coating material that is known in the art, such as conductive tape, conductive paint, and conductive silver paint.

In the illustrated embodiment, holes 26a, 26b and 26 are formed in non-conductive coating 22 such that conductive coating 24 may extend therethrough to contact each of ground pads 16a, 16b and 16c. It should be understood, however, that conductive coating 24 need only contact a portion of a single ground pad in order to provide grounding to electronic circuit 10. Thus, non-conductive coating 22 may be applied such that a hole is formed above only a portion of one of these ground pads. Thus, it should be understood that the application of non-conductive coating 22 and conductive coating 24 may vary in accordance with the present invention.

With reference generally to the exemplary embodiments of FIGS. 2 and 3-4, it should be understood that the non-conductive and conductive coatings should be compatible (both in the type and thickness of the coatings) so as to avoid any adverse chemical reactivity or degradation of the coatings. In a preferred exemplary embodiment, the non-conductive coating comprises non-conductive masking tape with RTV compound as additional non-conductive insulation, and the conductive coating comprises silver paint. For example, in testing an electronic circuit including a Raltron RTXT-681 oscillator (running at 39.984 megahertz) and a 74LS 169 binary bi-directional counter, good results were achieved when 3M printed circuit board masking tape was used as the non-conductive coating applied over the oscillator and counter (with RTV compound used as additional non-conductive insulation around such components) and silver paint was used as the conductive coating. This combination achieved a 20 decibel (db) attenuation of electromagnetic emissions in the ultra-high frequency (UHF) range, with less dramatic attenuation of lower frequency electromagnetic emissions. Of course, other combinations of non-conductive coatings and conductive coatings are also possible.

It should also be understood that the non-conductive coating is preferably thick enough to prevent arcing between the electrical components and the ground plane. One skilled in the art will appreciate that this thickness will vary between different types of electronic circuits. For example, digital circuits (which are powered at relatively low voltages) would not require as thick of a coating as RF circuits (which are powered at higher voltages). Also, higher RF frequencies would require a thicker coating than lower RF frequencies. In addition, the conductive coating is preferably thick enough to allow the flow of RF current, which occurs on the surface of the conductor. Preferably, the conductive coating is at least two skin depths in thickness, wherein:
skin depth=1/(pi*f*u*c)^{0.5} meters

and
f=frequency (in Hz)
u=permeability (in henries/meter)
c=conductivity (in mhos/meter)

One skilled in the art will appreciate that the present invention may be used in various electronic circuit applications in which shielding of electromagnetic emissions from all or a portion of the electronic circuit is desired. For example, in a radio receiver application, the front-end circuit can be especially susceptible to the electromagnetic emissions generated by the digital signal processor (DSP). The invention may be used in such an application to effectively shield the DSP, thereby alleviating the necessity to reduce the sensitivity of the front-end circuit in order to avoid detection of undesired electromagnetic emissions.

Finally, it should be understood that the present invention may be implemented more easily and at a lower manufacturing cost than the metal cage or wire mesh shields that are presently known in the art. In addition, because the non-conductive coating and conductive coating preferably conform to the profile of the electronic circuit, the shielding occupies a minimal amount of space. Of course, other advantages of the invention should be apparent to those skilled in the art.

While the present invention has been described and illustrated hereinabove with reference to several exemplary embodiments, it should be understood that various modifications could be made to these embodiments without departing from the scope of the invention. Therefore, the invention is not to be limited to the specific embodiments described and illustrated hereinabove, except insofar as such limitations are included in the following claims.

What is claimed and desired to be secured by Letters Patent is as follows:

1. A method of reducing electromagnetic emissions from an electronic circuit, said electronic circuit comprising at least one electrical component and at least one grounding point, said method comprising:
applying a non-conductive coating over said electrical component; and
applying a conductive coating over said non-conductive coating and in contact with said grounding point so as to ground said conductive coating and thereby reduce electromagnetic emissions from said electronic circuit.

2. The method of claim 1, wherein a hole is formed in said non-conductive coating above said grounding point so as to enable contact between said conductive coating and said grounding point.

3. The method of claim 1, wherein said grounding point is located proximate an edge of said electronic circuit, and wherein said non-conductive coating does not coat said edge of said electronic circuit so as to enable contact between said conductive coating and said grounding point.

4. The method of claim 1, wherein said non-conductive coating conforms to said electrical component, and wherein said conductive coating conforms to said non-conductive coating and said grounding point.

5. An electronic circuit comprising at least one electrical component and at least one grounding point, wherein a non-conductive coating is applied over said electrical component, and wherein a conductive coating is applied over said non-conductive coating and in contact with said grounding point so as to ground said conductive coating.

6. The electronic circuit of claim 5, wherein a hole is formed in said non-conductive coating above said grounding point so as to enable contact between said conductive coating and said grounding point.

7. The electronic circuit of claim 5, wherein said grounding point is located proximate an edge of said electronic circuit, and wherein said non-conductive coating does not coat said edge of said electronic circuit so as to enable contact between said conductive coating and said grounding point.

8. The electronic circuit of claim 5, wherein said non-conductive coating conforms to said electrical component, and wherein said conductive coating conforms to said non-conductive coating and said grounding point.

9. The electronic circuit of claim 5, wherein said non-conductive coating comprises a conformal coating material selected from the following group: insulating tape, rubber, silicone, room-temperature vulcanizing silicone rubber, plastic, insulating varnish, and combinations thereof.

10. The electronic circuit of claim 5, wherein said conductive coating comprises a conformal coating material selected from the following group: conductive tape, conductive paint, silver paint, and combinations thereof.

11. The electronic circuit of claim 5, wherein said non-conductive coating is applied over a plurality of electrical components of said electronic circuit.
